(19) United States
(12) Patent Application Publication
(10) Pub. No.: US 2010/0062592 A1
(43) Pub. Date: Mar. 11, 2010

(54) METHOD FOR FORMING GATE SPACERS FOR SEMICONDUCTOR DEVICES

(75) Inventor: Robert D. Clark, Schenectady, NY (US)

Correspondence Address: Tokyo Electron U.S. Holdings, Inc., 4350 West Chandler Blvd., Suite 10/11, Chandler, AZ, 85226, US

(73) Assignee: TOKYO ELECTRON LIMITED, Tokyo (JP)

(21) Appl. No.: 12/206,949

(22) Filed: Sep. 9, 2008

(51) Int. Cl. H01L 21/3205

(52) U.S. Cl. 438/591; 257/E21.207

(57) ABSTRACT

A method for forming gate spacers for semiconductor devices includes forming a patterned gate structure on substrate, where the patterned gate structure contains an interface layer on the substrate, a high-k film on the interface layer, and a gate electrode on the high-k film. The method further includes depositing a nitride barrier layer on the patterned gate structure using processing conditions that minimize or prevent oxidation of the substrate and the gate electrode, depositing a spacer material on the nitride barrier layer, and anisotropically etching the spacer material to form a gate spacer on the patterned gate structure.

### FIELD OF INVENTION

The present invention relates generally to the field of fabrication of semiconductor devices, and more particularly, to a method for fabricating a gate spacer on a sidewall of a patterned gate structure of a semiconductor device.

### BACKGROUND OF THE INVENTION

In the semiconductor industry, the minimum feature sizes of microelectronic devices are approaching the deep sub-micron regime to meet the demand for faster, lower power microprocessors and digital circuits. Metal oxide semiconductor field effect transistors (MOSFETs) have been continuously scaled down to gain improved device density, operating performance, and reduced fabrication cost for integrated circuits (ICs).

A gate spacer formed around a patterned gate structure of a MOSFET is typically used as an implant mask in a self aligned drain and source implantation. In addition, the gate spacer is used to isolate drain/source electrodes from a patterned gate structure when the drain/source electrodes are formed through a silicide formation process. Formation of a conventional gate spacer around a patterned gate structure frequently results in unwanted oxidation of the patterned gate structure that can affect device performance. For example, oxidation of the sidewalls of the patterned gate structure in contact with the gate spacer and oxidation of the substrate beneath the patterned gate structure that results in an increase in the thickness of a dielectric interface layer has detrimental effects on the device performance and the reliability of the device. Accordingly, further developments are required to address unwanted oxidation and other problems associated with integrating gate spacers with gate structures for semiconductor devices.

### SUMMARY OF THE INVENTION

Embodiments of the invention provide a method for integrating formation of gate spacers around patterned gate structures into semiconductor manufacturing. The method prevents or minimizes formation of an oxidized gate electrode region that can increase in the equivalent oxide thickness (EOT) of the patterned gate structure and changes in the effective workfunction of the patterned gate structure near the source/drain regions.

According to one embodiment of the invention, the method includes forming a patterned gate structure on a substrate, the patterned gate structure containing an interface layer on the substrate, a high-k film on the interface layer, and a gate electrode on the high-k film. The method further includes depositing a nitride barrier layer on the patterned gate structure in a process chamber using processing conditions that minimize oxidation of the substrate and the gate electrode. Deposition of the nitride barrier layer includes exposing the patterned gate structure to a process gas containing a nitride precursor at a substrate temperature below 400° C., and maintaining a partial pressure of oxygen-containing gases below 1×10⁻⁴ Torr in the process chamber during the exposing. The method further includes depositing a spacer material on the nitride barrier layer; and anisotropically etching the spacer material to form a gate spacer on the patterned gate structure. According to one embodiment, the nitride barrier layer and the spacer material can contain silicon nitride or silicon carbonitride. According to another embodiment, the nitride barrier layer can containing silicon nitride or silicon carbonitride and the spacer material can contain SiO₂.

### BRIEF DESCRIPTION OF THE DRAWINGS

In the accompanying drawings:

FIG. 1A shows a schematic cross-sectional view of a conventional patterned gate structure containing a gate spacer;

FIG. 1B is an exploded view of a portion of the patterned gate structure in FIG. 1A;

FIGS. 2A-2E show schematic cross-sectional views of a process flow for forming a patterned gate structure containing a gate spacer according to an embodiment of the invention;

FIG. 2F is an exploded view of a portion of the patterned gate structure in FIG. 2E;

FIG. 3 depicts a schematic view of a vacuum processing tool for processing a substrate according to embodiments of the invention;

FIG. 4 is a process flow diagram for forming a patterned gate structure containing a gate spacer according to embodiments of the invention; and

FIG. 5 depicts a schematic view of a processing system for processing a substrate according to embodiments of the invention.

### DETAILED DESCRIPTION OF SEVERAL EMBODIMENTS

Methods for forming patterned gate structures containing a gate spacer for semiconductor devices are disclosed in various embodiments. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Furthermore, it is understood that the various embodiments shown in the drawings are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. In this detailed description, like parts are designated by like reference numbers throughout the several drawings.

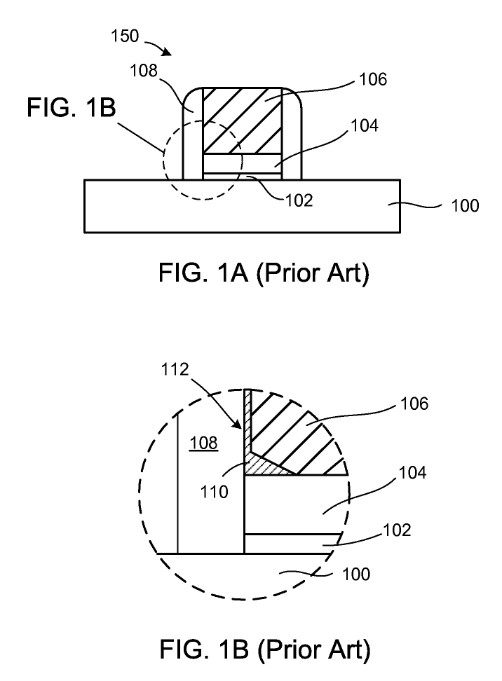

FIG. 1A is a schematic cross-sectional view of a conventional gate spacer 108 around a patterned gate structure 150 on a substrate 100 and FIG. 1B is an exploded view of a portion of the patterned gate structure 150 in FIG. 1A. The patterned gate structure 150 contains an interface layer 102 on the substrate 100, a high dielectric constant (high-k) film 104 on the interface layer 102, and a gate electrode 106 on the high-k film 104. FIG. 1A further shows gate spacer 108 formed on the sidewall 112 of the patterned gate structure 150. The exploded view in FIG. 1B shows an oxidized gate electrode region 110 formed during formation of the gate spacer 108 around the patterned gate structure 150 by reaction of one or more oxygen-containing gases with the sidewall 112 of the gate electrode 106 and with a portion of the gate electrode 106 at the interface with the high-k film 104 near the sidewall 112 of the gate electrode 106. The formation of the oxidized gate electrode region 110 has several detrimental effects on a semiconductor device containing the patterned gate structure 150, including 1) increase in the equivalent oxide thickness (EOT) of the patterned gate structure and 2) changes in the effective workfunction of the patterned gate structure near the source/drain regions. The changes in the effective workfunction can result in threshold voltage shifts that can make the device unstable during operation and reduce the reliability of the device.

Embodiments of the invention address the need for preventing or minimizing unwanted oxidation of a gate electrode and other problems associated with integrating a gate spacer with a patterned gate structure for a semiconductor device. To this effect, embodiments of the invention include depositing a nitride barrier layer on a patterned gate structure using processing conditions that prevent or minimize oxidation of the substrate and the gate electrode, including the sidewalls of the gate electrode. The current inventors have realized that processing conditions that include a substrate temperature below 400° C. and partial pressure of oxygen-containing gases below 1×10⁻⁴ Torr are required to deposit a nitride barrier layer while preventing or minimizing the oxidation of the substrate and the gate electrode. The oxygen-containing gases may be background gases in a process chamber of a processing system configured for forming the gate spacer. The oxygen-containing gases may, at least in part, originate from a process gas used to deposit the nitride barrier layer. The most common oxygen-containing background gases are water (H₂O), oxygen (O₂), and carbon dioxide (CO₂), but may also include organic gases such as alcohols.

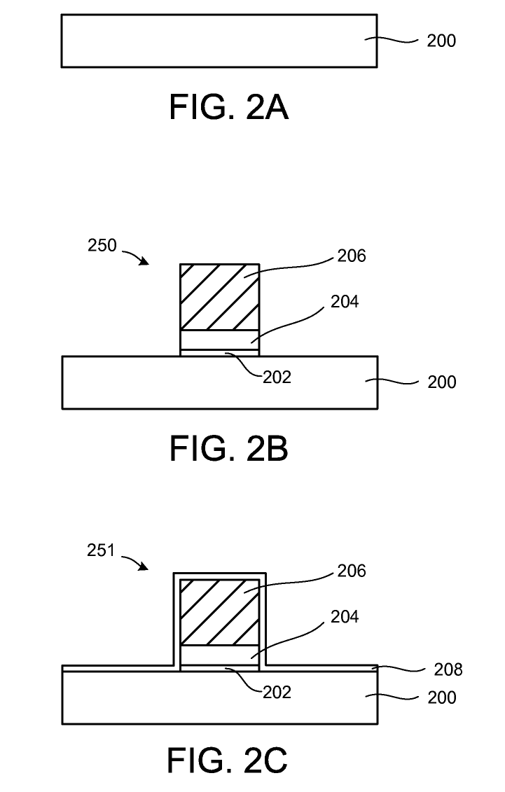

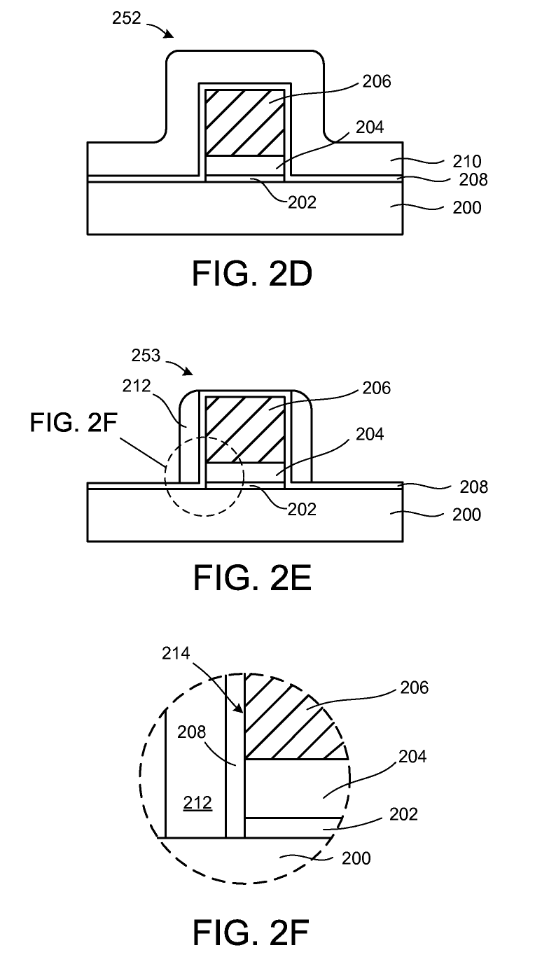

FIGS. 2A-2E show schematic cross-sectional views of a process flow for forming a patterned gate structure containing a gate spacer according to an embodiment of the invention. In FIG. 2A, a substrate 200, such as a silicon substrate, is provided. FIG. 2B shows a patterned gate structure 250 that is a stacked structure containing an interface layer 202, a high-k film 204 over the interface layer 202, and a gate electrode 206 over the high-k film 204. The substrate 200 may be 200 mm Si substrate (wafer), a 300 mm Si substrate, or an even larger substrate. The interface layer 202 may contain SiO₂ or SiON, for example.

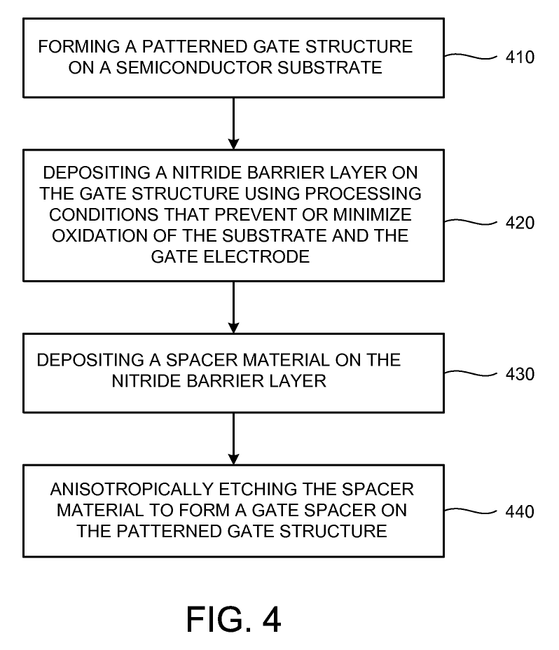

Methods for forming the patterned gate structure 250 depicted in FIG. 2B are well known to those skilled in the art. For example, the patterned gate structure 250 may be formed by depositing a stacked film structure containing an interface layer on the substrate 200, a high-k film on the interface layer, and a gate electrode on the high-k film. Next, the stacked film structure is masked and subsequently dry etched to form the patterned gate structure 250, using the substrate 200 as an etch stop. According to other embodiments, the interface layer may be used as an etch stop and thus, in FIG. 2B, the interface layer 202 may also be present on the substrate 200 around the patterned gate structure 250. A method for forming the patterned gate structure 250 according to embodiments of the invention is further described below in reference to FIG. 4.

The high-k film 204 contains a dielectric material featuring a dielectric constant greater than that of SiO₂ (k˜3.9). The high-k film 204 can contain one or more metal elements selected from alkaline earth elements, rare earth elements, and Group IVB elements of the Periodic Table of the Elements, for example. The high-k material can include metal oxides, metal oxynitrides, or metal nitrides of those elements. Alkaline earth metal elements include beryllium (Be), magnesium (Mg), calcium (Ca), strontium (Sr), and barium (Ba). Exemplary oxides include magnesium oxide, calcium oxide, and barium oxide, and combinations thereof. Rare earth metal elements may be selected from the group of scandium (Sc), yttrium (Y), lutetium (Lu), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), and ytterbium (Yb). The Group IVB elements include titanium (Ti), hafnium (Hf), and zirconium (Zr). According to some embodiments of the invention, the high-k film 204 may contain HfO₂, HfON, ZrO₂, ZrON, TiO₂, TiON, Al₂O₃, La₂O₃, W₂O₃, CeO₂, Y₂O₃, or Ta₂O₅, or a combination of two or more thereof. However, other high-k materials are contemplated and may be used.

The gate electrode 206 can contain poly Si, a metal-containing layer, or both poly Si and a metal-containing layer. The metal-containing layer can, for example, contain W, WN, WSi, Al, Mo, Ta, TaN, TaSiN, TaAlN, HfN, HfSiN, Ti, TiN, TiSiN, Mo, MoN, Re, Pt, or Ru, or a combination of two or more thereof. In one example, the gate electrode 206 can contain poly Si in direct contact with the high-k film 204 and one or more metal-containing layers stacked above the poly Si. In another example, the gate electrode 206 can contain a metal-containing layer in direct contact with the high-k film 204.

FIG. 2C shows a patterned gate structure 251 containing a nitride barrier layer 208 formed over the exposed surfaces of the patterned gate structure 251, including on exposed sidewalls of the gate electrode 206, exposed sidewalls of the high-k film 204, on the exposed sidewalls of the interface layer 202, and on the substrate 200 around the patterned gate structure 251. According to embodiments of the invention, the nitride barrier layer 208 is deposited using processing conditions that prevent or minimize oxidation of the sidewalls of the gate electrode 206. The processing conditions include substrate temperature below 400° C. and partial pressure of oxygen-containing gases below 1×10⁻⁴ Torr. A thickness of the nitride barrier layer 208 can be only a few atomic layers thick, for example between about 10 angstrom and about 50 angstrom thick, or between about 20 angstrom and about 50 angstrom thick. However, in some embodiments of the invention, the nitride barrier layer 208 may be thicker than 50 angstrom.

According to embodiments of the invention, the nitride barrier layer 208 may contain silicon nitride, silicon carbonitride, or a combination thereof. As used herein, silicon nitride (SiₓN_{y}) is simply denoted as SiN and refers to a material containing silicon and nitrogen as the major elements. The silicon nitride composition can, for example, range from having approximately equal amounts of silicon and nitrogen to Si₃N₅. Furthermore, as used herein, silicon carbonitride (SiₓC_{z}N_{y}) is simply denoted as SiCN and refers to a material containing silicon, nitrogen, and carbon as the major elements. In one example, the silicon carbonitride material can contain approximately 50 atomic percent Si and approximately equal amounts of N and C. In another example, the silicon carbonitride material may contain approximately 10-40 atomic percent C. The nitride barrier layer 208 may be formed by atomic layer deposition (ALD), plasma-enhanced ALD (PEALD), chemical vapor deposition (CVD), or plasma-enhanced CVD.

FIG. 2D shows a patterned gate structure 252 containing a spacer material 210 deposited over the nitride barrier layer 208. The spacer material 210 may contain SiN, SiCN, or a combination thereof. In another example, the spacer material 210 may be selected from SiN and SiCN. In yet another example, the spacer material 210 may contain SiN, SiCN, or SiO₂, or a combination thereof. According to one embodiment, the spacer material 210 may be deposited by CVD or PECVD. According to embodiments of the invention, the nitride barrier layer 208 acts as an oxidation barrier to reduce or prevent oxidation of the substrate 200 and the gate electrode 204 during deposition of the spacer material 210 and during further processing of the patterned gate structure 253. Thus, the spacer material 210 may be deposited in the presence of higher partial pressure of oxygen-containing gases than during deposition of the nitride barrier layer 208.

FIG. 2E shows a gate spacer 212 covering the sidewalls of a patterned gate structure 253 following anisotropic etching of the patterned gate structure 252 in FIG. 2D. FIG. 2F is an exploded view of a portion of the patterned gate structure 253 in FIG. 2E. A comparison of the exploded views in FIG. 2F and FIG. 1B shows that the use of the nitride barrier layer 208 prevents or minimizes oxidation of the gate electrode 206, including the sidewall 214, by acting as an oxidation barrier during deposition of the spacer material 210 in FIG. 2D and formation of the gate spacer 212. This prevents or reduces any increase in the equivalent oxide thickness (EOT) of the patterned gate structure 253 and prevents or reduces any changes in the effective workfunction of the patterned gate structure 253 near the source/drain regions (not shown). Drain/source regions, channel regions, well regions or isolation regions can be formed in the substrate 200 according to well-known processes that, for the sake of brevity, are not described in detail herein.

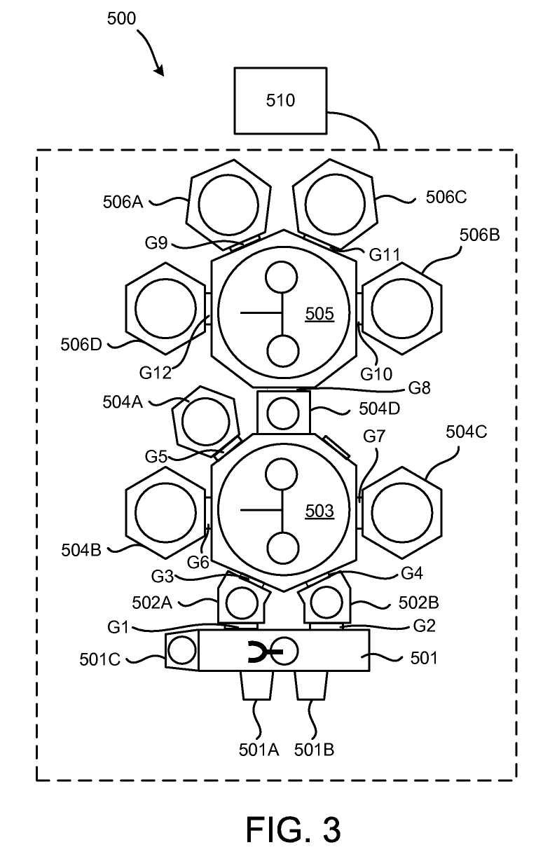

FIG. 3 is a schematic diagram of a vacuum processing tool for processing a substrate according to embodiments of the invention. The vacuum processing tool 500 contains a substrate (wafer) transfer system 501 that includes cassette modules 501A and 501B, and a substrate alignment module 501C. Load-lock chambers 502A and 502B are coupled to the substrate transfer system 501 using gate valves G1 and G2, respectively. The substrate transfer system 501 is maintained at atmospheric pressure but a clean environment is provided by purging with an inert gas.

The load lock chambers 502A and 502B are coupled to a substrate transfer system 503 using gate valves G3 and G4. The substrate transfer system 503 may, for example, be maintained at a base pressure of 1×10⁻⁶ Torr, or lower, using a turbomolecular pump (not shown). The substrate transfer system 503 includes a substrate transfer robot and is coupled to processing system 504A, and gate electrode deposition systems 504B and 504C. In one example, the gate electrode deposition system 504B may be configured for depositing a poly Si layer or a first metal-containing layer, and the gate electrode deposition system 504C may be configured for depositing a second metal-containing layer on the poly Si layer or on the first metal containing layer. The first and second metal-containing layers can, for example, contain W, WN, WSix, Al, Mo, Ta, TaN, TaSiN, TaAlN, HfN, HfSiN, Ti, TiN, TiSiN, Mo, MoN, Re, Pt, or Ru, or a combination of two or more thereof. The processing systems 504A, 504B, and 504C are coupled to the substrate transfer system 503 using gate valves G5, G6, and G7, respectively.

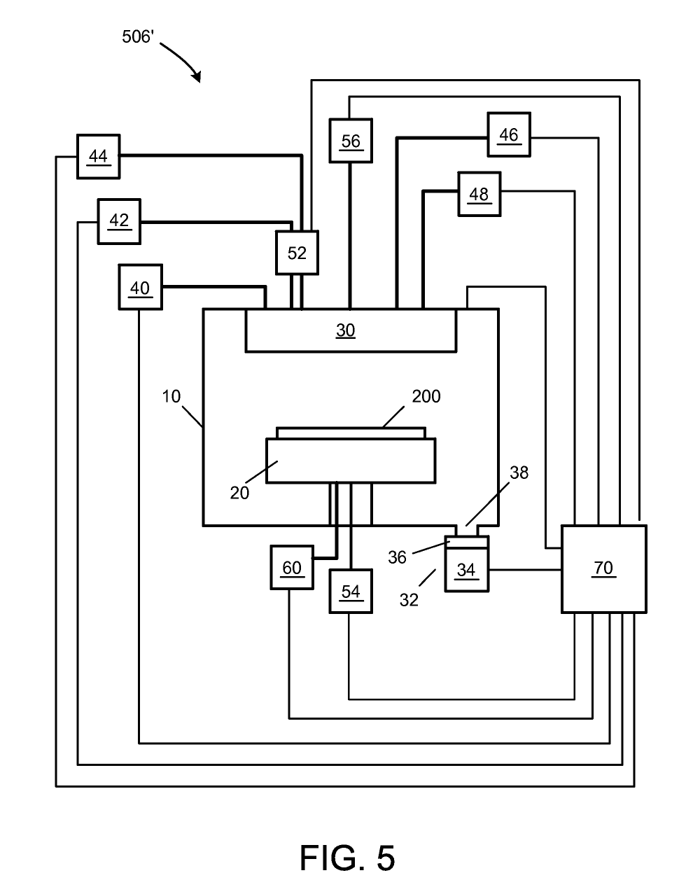

Furthermore, the substrate transfer system 503 is coupled to a substrate transfer system 505 through substrate handling chamber 504D and gate valve G8. As in the substrate transfer system 503, the substrate transfer system 505 may be maintained at a base pressure of 1×10⁻⁶ Torr, or lower, using a turbomolecular pump (not shown). The substrate transfer system 505 includes a substrate transfer robot. Coupled to the substrate transfer system 505 is processing system 506D for depositing a nitride barrier layer (e.g., SiN or SiCN), processing system 506A for depositing a spacer material (e.g., SiN, SiCN, or SiO₂), processing system 506B for depositing a high-k film, and nitriding/oxidizing processing system 506C. The processing systems 506A, 506B, and 506D may be configured for performing ALD, PEALD, CVD, or PECVD, for example. An exemplary processing system capable of performing ALD, PEALD, CVD, or PECVD is depicted in FIG. 5.

In one example, the processing system 506C may be a plasma processing system containing a slot plane antenna (SPA) plasma source from Tokyo Electron Limited, Akasaka, Japan. Further details of a plasma processing system containing a slot plane antenna plasma source and methods of using are described in European Patent No. EP1361605, titled “METHOD FOR PRODUCING MATERIAL OF ELECTRONIC DEVICE”, the entire contents of which is hereby incorporated by reference.

In another example, the processing system 506C may be a plasma processing system containing an ultra-violet (UV) radiation plasma source and a remote plasma source. Such a processing system is described in European Patent No. EP1453083A1, titled “NITRIDING METHOD FOR INSULATION FILM, SEMICONDUCTOR DEVICE AND PRODUCTION METHOD FOR SEMICONDUCTOR DEVICE, SUBSTRATE TREATING DEVICE AND SUBSTRATE TREATING METHOD”, the entire contents of which is hereby incorporated by reference.

Processing systems 506A-506D are coupled to the substrate transfer system 505 using gate valves G9, G10, G11, and G12, respectively. The substrate transfer system 505 processing system 506D, an optionally processing systems 506C and 506D are capable of maintaining a base pressure of background gases at 1×10⁻⁶ Torr, or lower, during the integrated processing, thereby enabling formation of multilayer film structures with excellent film and film interface properties. In one example, the substrate transfer system 505 and the processing systems 506A-506D may be pumped by turbomolecular pumps. As those skilled in the art will readily recognize, a base pressure of 1×10⁻⁶ Torr, and lower, may be reached and maintained by carefully selecting the materials used to construct the processing systems and substrate transfer systems of the vacuum processing tool 500.

The vacuum processing tool 500 includes a controller 510 that can be coupled to and control any or all of the processing systems and processing elements depicted in FIG. 5 during the integrated substrate processing. Alternatively, or in addition, controller 510 can be coupled to one or more additional controllers/computers (not shown), and controller 510 can obtain setup and/or configuration information from an additional controller/computer. The controller 510 can be used to configure any or all of the processing systems and processing elements, and the controller 510 can collect, provide, process, store, and display data from any or all of the processing systems and processing elements. The controller 510 can comprise a number of applications for controlling any or all of the processing systems and processing elements. For example, controller 510 can include a graphic user interface (GUI) component (not shown) that can provide easy to use interfaces that enable a user to monitor and/or control one or more processing systems processing elements.

The controller 510 can include a microprocessor, memory, and a digital I/O port capable of generating control voltages sufficient to communicate, activate inputs, and exchange information with the vacuum processing tool 500 as well as monitor outputs from the vacuum processing tool 500. For example, a program stored in the memory may be utilized to activate the inputs of the vacuum processing tool 500 according to a process recipe in order to perform integrated substrate processing.

The controller 510 may be implemented as a general purpose computer system that performs a portion or all of the microprocessor based processing steps of the invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The controller 510 includes at least one computer readable medium or memory, such as the controller memory, for holding instructions programmed according to the teachings of the invention and for containing data structures, tables, records, or other data that may be necessary to implement the present invention. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, the present invention includes software for controlling the controller 510, for driving a device or devices for implementing the invention, and/or for enabling the controller 510 to interact with a human user. Such software may include, but is not limited to, device drivers, operating systems, development tools, and applications software. Such computer readable media further includes the computer program product of the present invention for performing all or a portion (if processing is distributed) of the processing performed in implementing the invention.

The computer code devices of the present invention may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor of the controller 510 for execution. A computer readable medium may take many forms, including but not limited to, non-volatile media, volatile media, and transmission media. Non-volatile media includes, for example, optical, magnetic disks, and magneto-optical disks, such as the hard disk or the removable media drive. Volatile media includes dynamic memory, such as the main memory. Moreover, various forms of computer readable media may be involved in carrying out one or more sequences of one or more instructions to processor of controller for execution. For example, the instructions may initially be carried on a magnetic disk of a remote computer. The remote computer can load the instructions for implementing all or a portion of the present invention remotely into a dynamic memory and send the instructions over a network to the controller 510.

The controller 510 may be locally located relative to the vacuum processing tool 500, or it may be remotely located relative to the vacuum processing tool 500. For example, the controller 510 may exchange data with the vacuum processing tool 500 using at least one of a direct connection, an intranet, the Internet and a wireless connection. The controller 510 may be coupled to an intranet at, for example, a customer site (i.e., a device maker, etc.), or it may be coupled to an intranet at, for example, a vendor site (i.e., an equipment manufacturer). Additionally, for example, the controller 510 may be coupled to the Internet. Furthermore, another computer (i.e., controller, server, etc.) may access, for example, the controller 510 to exchange data via at least one of a direct connection, an intranet, and the Internet. As also would be appreciated by those skilled in the art, the controller 510 may exchange data with the vacuum processing tool 500 via a wireless connection.

As those skilled in the art will readily recognize, embodiments of the invention may not require the use of all the processing systems of the vacuum processing tool 500 depicted in FIG. 3. For example, according to one embodiment, only one of the gate electrode deposition systems 504B, 504C may be needed to deposit a gate electrode material. Thus, some embodiments of the invention may include the use of less than all the processing systems depicted in FIG. 3.

FIG. 4 is a process flow diagram for forming a patterned gate structure containing a gate spacer according to embodiments of the invention. In 410, a patterned gate structure 250 is formed on substrate 200. According to one embodiment of the invention, the patterned gate structure 250 may be formed on substrate 200 in the vacuum processing tool 500 in FIG. 3. The substrate 200 depicted in FIG. 2A is positioned in the cassette modules 501A or 501B in the vacuum processing tool 500. The substrate 200 is introduced into the substrate transfer system 503 from the substrate transfer system 501 through the gate valve G1 and the load lock chamber 502A or through the gate valve G2 and the load lock chamber 502B, after a substrate aligning step in the substrate alignment module 501C. The substrate 200 is then transferred from the substrate transfer system 503 to the processing system 504A through the gate valve G5. In the processing system 504A, the substrate 100 is degassed by heating and/or by exposure to ultraviolet irradiation in an inert gas environment to remove water and any residual gas from surfaces of the substrate 200 and at least partially remove the contaminants from the substrate 200.

After degassing in the processing system 504A, the substrate 200 is returned to the substrate transfer system 503 through the gate valve G5 and then transported through the gate valve G8 to the substrate transfer system 505.

Once in the substrate transfer system 505, the substrate 200 is introduced into the processing system 506C through the gate valve G11 for forming an interface layer on the substrate 200. The interface layer can contain SiO₂, SiON, or a combination thereof. The interface layer may be only a few angstrom thick, for example between about 5 angstrom and about 20 angstrom. Next, the substrate 200 is returned to the substrate transfer system 505 through the gate valve G1 and then introduced into the processing system 506B through the gate valve G10 for depositing a high-k film on the substrate 200. Next, the substrate 200 is returned to the substrate transfer system 505 through the gate valve G10 and transferred to the substrate transfer system 503 through substrate handling chamber 504D and gate valve G8. Next, a gate electrode is deposited on the substrate 200 in gate electrode deposition system 504B, gate electrode deposition system 504C, or in both systems 504B and 504C. Next, the substrate 200 is returned to the substrate transfer system 501 from the substrate transfer system 503 through the gate valve G3, load lock chamber 502A and the gate valve G1, or through the gate valve G4, the load lock chamber 502B and the gate valve G2. Thereafter, the substrate 200 is returned to the cassette module 501A or 501B and removed from the vacuum processing tool 500. Next further processing is performed that includes masking the stacked film structure containing the gate electrode, the high-k film, and the interface layer, and then stacked film structure is dry etching to form the patterned gate structure 250 on the substrate 200 depicted in FIG. 2B. Patterning processes that may be used to form the patterned gate structure 250 are well known to those skilled in the art and can include photolithography and dry etching processes.

According to one embodiment of the invention, further processing of the patterned gate structure 250 may be performed in the vacuum processing tool 500. Referring still to FIG. 4, in 420, a nitride barrier layer 208 is deposited over the patterned gate structure 250 on the substrate 200. The substrate 200 is introduced into the vacuum processing tool 500 and into the substrate transfer system 505 as described above. Once in the substrate transfer system 505, the substrate 200 is introduced into the processing system 506D through the gate valve G12 for depositing the nitride barrier layer 208 using processing conditions that prevent or minimize oxidation of the substrate 200 and the gate electrode 206. The nitride barrier layer 208 can be only a few atomic layers thick with a thickness between about 10 angstrom and about 50 angstrom, for example. In another example, the thickness can be between about 20 angstrom and about 50 angstrom. However, in some embodiments of the invention, the nitride barrier layer 208 may be thicker than 50 angstrom.

Following deposition of the nitride barrier layer 208, the substrate 200 is returned to the substrate transfer system 505 through the gate valve G12 and then introduced into the processing system 506A through gate valve G9 for depositing, in 430, a spacer material 210 on the nitride barrier layer 208 as depicted in FIG. 2D. The spacer material 210 can SiN, SiCN, or SiO₂, or a combination thereof. A thickness of the spacer material 210 can, for example, be between about 100 langstrom and about 1000 angstrom. Thus, the spacer material 210 may be thicker than the nitride barrier layer 208, as schematically depicted in FIG. 2D. According to one embodiment of the invention, the nitride barrier layer 208 may be deposited with a first deposition rate by ALD or PEALD and the spacer material 210 may be deposited with a second deposition by CVD or PECVD, where the second deposition rate is greater than the first deposition rate. This can result in reduced processing time. According to one embodiment of the invention, the nitride barrier layer 208 and the spacer material 210 may be deposited in the same processing system, for example processing system 506D. Furthermore, since the nitride barrier layer 208 can act as an oxidation barrier, deposition of the spacer material 210 may be performed using substrate temperature greater than 400° C. and partial pressure of oxygen-containing gases greater than 1×10⁻⁴ Torr.

After deposition of the spacer material 210, the substrate 200 is returned to the substrate transfer system 505 through the gate valve G9 and to the substrate transfer system 503 and removed from the vacuum processing tool 500 as described above. In 440, the spacer material 210 is anisotropically etched to form the patterned gate structure 253 depicted in FIG. 2E containing gate spacer 212.

FIG. 5 depicts a schematic view of a processing system 506′ for processing a substrate according to embodiments of the invention. The processing system 506′ may be configured for depositing a nitride diffusion barrier (e.g., processing system 506D), depositing a spacer material (e.g., processing system 506A), or depositing a high-k film (e.g., processing system 506B) by ALD, PEALD, CVD, or PECVD processing. The processing system 506′ includes a process chamber 10 having a substrate holder 20 configured to support a substrate 200, upon which a film is formed. The process chamber 10 further contains an assembly 30 (e.g., a showerhead) coupled to a metal precursor supply system 40, a nitrogen source supply system 42, an oxygen source supply system 44, a silicon source supply system 46, and a purge gas supply system 48. The processing system 506′ may be configured to process 200 mm substrates, 300 mm substrates, or larger-sized substrates. In fact, it is contemplated that the processing system 506′ may be configured to process substrates, wafers, or flat panels regardless of their size, as would be appreciated by those skilled in the art. Therefore, while aspects of the invention will be described in connection with the processing of a semiconductor substrate, the invention is not limited solely thereto.

The purge gas supply system 48 is configured to introduce a purge gas to the process chamber 10. For example, the introduction of the purge gas may occur between introduction of gas pulses to the process chamber 10 during ALD or PEALD processing. The purge gas can comprise an inert gas, such as a noble gas (i.e., He, Ne, Ar, Kr, or Xe), nitrogen (N₂), or hydrogen (H₂).

The nitrogen source supply system 42 is configured to introduce a nitrogen-containing gas to the process chamber 10. The nitrogen-containing gas can include N₂, NH₃, N₂H₄, or a combination thereof.

The oxygen source supply system 44 is configured to flow an oxygen-containing gas to the process chamber 10. The oxygen-containing gas can include O₂, H₂O, H₂O₂, or a combination thereof, into the process chamber 10 through the assembly 30.

The silicon source supply system 46 is configured to flow a silicon-containing gas to the process chamber 10. Examples of silicon-containing gases include SiH₄, Si₂H₆, SiCl₄, SiCl₃H, SiCl₂H₂, SiClH₃, Si₂Cl₆, ((CH₃)₂N)₃SiH (tris(dimethylamino) silane, ((CH₃)₂N)₂SiH₂ (bis(dimethylamino) silane, ((CH₃)₂N)₄Si) (tetrakis(dimethylamino)silane), methylsilane (H₃C—SiH₃), dimethylsilane (H₃C—SiH₂—CH₃), trimethylsilane ((CH₃)₃—SiH), or tetramethylsilane ((CH₃)₄—Si), or any combination of two or more thereof. The silicon-containing gas is also referred to herein as a SiN or SiCN precursor. Furthermore, as used herein, a nitride precursor may comprise a silicon-containing gas.

The processing system 506′ includes a plasma generation system configured to generate a plasma during at least a portion of the gas exposures in the process chamber 10. The oxygen source supply system 44 may be configured to flow O₂ gas to remote plasma system 52 where the O₂ gas is plasma excited to form an O₃+O₂ mixture. An exemplary O₃+O₂ mixture contains about 5% O₃, balance O₂. Furthermore, the nitrogen source supply system 42 may be configured to flow N₂ or NH₃ gas to the remote plasma system 52 to form excited nitrogen species (e.g., N* or NHₓ*(x≦3). The remote plasma system 52 can, for example, contain a microwave frequency generator. The O₃+O₂ mixture or the plasma excited nitrogen species are then introduced into the process chamber 10 through the assembly 30 and exposed to the substrate 200. Alternatively oxygen radicals (O) may be produced from O₂ gas or excited nitrogen species may be produces form N₂ or NH₃ gas in the process chamber 10 by a plasma using a first power source 56 coupled to the process chamber 10, and configured to couple power to gases introduced into the process chamber 10 through the assembly 30. The first power source 56 may be a variable power source and may include a radio frequency (RF) generator and an impedance match network, and may further include an electrode through which RF power is coupled to the plasma in process chamber 10. The electrode can be formed in the assembly 30, and it can be configured to oppose the substrate holder 20. The impedance match network can be configured to optimize the transfer of RF power from the RF generator to the plasma by matching the output impedance of the match network with the input impedance of the process chamber, including the electrode, and plasma. For instance, the impedance match network serves to improve the transfer of RF power to plasma in process chamber 10 by reducing the reflected power. Match network topologies (e.g. L-type, π-type, T-type, etc.) and automatic control methods are well known to those skilled in the art.

Alternatively, the first power source 56 may further include an antenna, such as an inductive coil, through which RF power is coupled to plasma in process chamber 10. The antenna can, for example, include a helical or solenoidal coil, such as in an inductively coupled plasma source or helicon source, or it can, for example, include a flat coil as in a transformer coupled plasma source. Alternatively, the first power source 56 may include a microwave frequency generator, and may further include a microwave antenna and microwave window through which microwave power is coupled to plasma in process chamber 10. The coupling of microwave power can be accomplished using electron cyclotron resonance (ECR) technology, or it may be employed using surface wave plasma technology, such as a slotted plane antenna (SPA), as described in U.S. Pat. No. 5,024,716.

As those skilled in the art will readily recognize, the oxygen source supply system 44, the nitrogen source supply system 42, and the silicon source supply system 46 can be further configured to flow an inert gas, such as a noble gas, into the process chamber 10.

The processing system 506′ further includes a substrate bias generation system configured to optionally generate or assist in generating a plasma (through substrate holder biasing) during at least a portion of the alternating introduction of the gases to the process chamber 10. The substrate bias system can include a substrate power source 54 coupled to the substrate holder 20, and configured to couple power to the substrate 100. The substrate power source 54 may include a RF generator and an impedance match network, and may further include an electrode through which RF power is coupled to substrate 100. The electrode can be formed in substrate holder 20. A typical frequency for the RF bias can range from about 0.1 MHz to about 100 MHz, and can be 13.56 MHz. RF bias systems for plasma processing are well known to those skilled in the art. Alternatively, RF power is applied to the substrate holder electrode at multiple frequencies. Although the plasma generation system and the substrate bias system are illustrated in FIG. 5 as separate entities, they may indeed comprise one or more power sources coupled to substrate holder 20.

Furthermore, processing system 506′ includes substrate temperature control system 60 coupled to the substrate holder 20 and configured to elevate and control the temperature of substrate 100. Substrate temperature control system 60 comprises temperature control elements, such as a cooling system including a re-circulating coolant flow that receives heat from substrate holder 20 and transfers heat to a heat exchanger system (not shown), or when heating, transfers heat from the heat exchanger system. Additionally, the temperature control elements can include heating/cooling elements, such as resistive heating elements, or thermoelectric heaters/coolers, which can be included in the substrate holder 20, as well as the chamber wall of the process chamber 10 and any other component within the processing system 506′. The substrate temperature control system 60 can, for example, be configured to elevate and control the temperature of the substrate 200 from room temperature to approximately 150° C. to 550° C. Alternatively, the temperature of the substrate can, for example, range from approximately 150° C. to 350° C. It is to be understood, however, that the temperature of the substrate 200 is selected based on the desired temperature for causing deposition of a particular film on a surface of the substrate 200.

In order to improve the thermal transfer between substrate 200 and substrate holder 20, substrate holder 20 can include a mechanical clamping system, or an electrical clamping system, such as an electrostatic clamping system, to affix substrate 200 to an upper surface of substrate holder 20. Furthermore, substrate holder 20 can further include a substrate backside gas delivery system configured to introduce gas to the back-side of substrate 200 in order to improve the gas-gap thermal conductance between substrate 200 and substrate holder 20. Such a system can be utilized when temperature control of the substrate 200 is required at elevated or reduced temperatures. For example, the substrate backside gas system can comprise a two-zone gas distribution system, wherein the helium gas gap pressure can be independently varied between the center and the edge of substrate 200.

Furthermore, the process chamber 10 is further coupled to a pressure control system 32, including a vacuum pumping system 34 and a valve 36, through a duct 38, wherein the pressure control system 32 is configured to controllably evacuate the process chamber 10 to a pressure suitable for forming a film on the substrate 200. The vacuum pumping system 34 can include a turbo-molecular vacuum pump (TMP) or a cryogenic pump capable of a pumping speed up to about 5000 liters per second (and greater) and valve 36 can include a gate valve for throttling the chamber pressure. Moreover, a device for monitoring chamber pressure (not shown) can be coupled to the process chamber 10. The pressure measuring device can be, for example, an absolute capacitance manometer. The pressure control system 32 can, for example, be configured to control the process chamber pressure between about 0.1 Torr and about 100 Torr during deposition a film on substrate 200.

The metal precursor supply system 40, the nitrogen source supply system 42, the oxygen source supply system 44, the silicon source supply system 46, and the purge gas supply system 48, can include one or more pressure control devices, one or more flow control devices, one or more filters, one or more valves, and/or one or more flow sensors. The flow control devices can include pneumatic driven valves, electromechanical (solenoidal) valves, and/or high-rate pulsed gas injection valves. According to embodiments of the invention, gases may be sequentially and alternately pulsed into the process chamber 10, where the length of each gas pulse can, for example, be between about 0.1 sec and about 100 sec. An exemplary pulsed gas injection system is described in greater detail in pending U.S. Patent Application Publication No. 2004/0123803.

Furthermore, the processing system 506′ includes a controller 70 that can be coupled to the process chamber 10, substrate holder 20, assembly 30 configured for introducing process gases into the process chamber 10, vacuum pumping system 34, metal precursor supply system 40, nitrogen source supply system 42, oxygen source supply system, purge gas supply system 48, silicon source supply system 46, remote plasma system 52, substrate power source 54, first power source 56, and substrate temperature control system 60. Alternatively, or in addition, controller 70 can be coupled to one or more additional controllers/computers (not shown), and controller 70 can obtain setup and/or configuration information from an additional controller/computer.

The controller 70 can comprise a microprocessor, memory, and a digital I/O port capable of generating control voltages sufficient to communicate and activate inputs to the processing system 506′ as well as monitor outputs from the processing system 506′. For example, a program stored in the memory may be utilized to activate the inputs to the aforementioned components of the processing system 506′ according to a process recipe in order to perform a deposition process. The controller 70 can comprise a number of applications for controlling one or more of the processing elements. For example, controller 70 can include a graphic user interface (GUI) component (not shown) that can provide easy to use interfaces that enable a user to monitor and/or control one or more processing elements.

However, the controller 70 may be implemented as a general purpose computer system that performs a portion or all of the microprocessor based processing steps of the invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The controller 70 includes at least one computer readable medium or memory, such as the controller memory, for holding instructions programmed according to the teachings of the invention and for containing data structures, tables, records, or other data that may be necessary to implement the present invention. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, resides software for controlling the controller 70, for driving a device or devices for implementing the invention, and/or for enabling the controller to interact with a human user. Such software may include, but is not limited to, device drivers, operating systems, development tools, and applications software. Such computer readable media further includes the computer program product of the present invention for performing all or a portion (if processing is distributed) of the processing performed in implementing the invention.

The computer code devices may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor of the controller 70 for execution. A computer readable medium may take many forms, including but not limited to, non-volatile media, volatile media, and transmission media. Non-volatile media includes, for example, optical, magnetic disks, and magneto-optical disks, such as the hard disk or the removable media drive. Volatile media includes dynamic memory, such as the main memory. Moreover, various forms of computer readable media may be involved in carrying out one or more sequences of one or more instructions to the processor of the controller 70 for execution. For example, the instructions may initially be carried on a magnetic disk of a remote computer. The remote computer can load the instructions for implementing all or a portion of the present invention remotely into a dynamic memory and send the instructions over a network to the controller 70.

The controller 70 may be locally located relative to the processing system 506′, or it may be remotely located relative to the processing system 506′. For example, the controller 70 may exchange data with the processing system 506′ using at least one of a direct connection, an intranet, the Internet and a wireless connection. The controller 70 may be coupled to an intranet at, for example, a customer site (i.e., a device maker, etc.), or it may be coupled to an intranet at, for example, a vendor site (i.e., an equipment manufacturer). Additionally, for example, the controller 70 may be coupled to the Internet. Furthermore, another computer (i.e., controller, server, etc.) may access, for example, the controller 70 to exchange data via at least one of a direct connection, an intranet, and the Internet. As also would be appreciated by those skilled in the art, the controller 70 may exchange data with the processing system 506′ via a wireless connection.

The metal precursor supply system 40 is configured to introduce a metal precursor containing one or more metal elements selected from alkaline earth elements, rare earth elements, and Group IVB elements of the Periodic Table of the Elements. The alternation of the introduction of the metal precursors can be cyclical, or it may be acyclical with variable time periods between the introduction of the one or more metal precursors. As those skilled in the art will readily recognize, the metal precursor supply system 40 can be configured to flow an inert gas, such as a noble gas, N₂, or H₂, into the process chamber 10.

Several methods may be utilized for introducing the metal precursors to the process chamber 10. One method includes vaporizing precursors through the use of separate bubblers or direct liquid injection systems, or a combination thereof, and then mixing in the gas phase within or prior to introduction into the process chamber 10. By controlling the vaporization rate of each metal precursor separately, a desired metal element stoichiometry can be attained within the film. Another method of delivering each metal precursor includes separately controlling two or more different liquid sources, which are then mixed prior to entering a common vaporizer. This method may be utilized when the metal precursors are compatible in solution or in liquid form and they have similar vaporization characteristics. Other methods include the use of compatible mixed solid or liquid precursors within a bubbler. Liquid source precursors may include neat liquid metal precursors, or solid or liquid metal precursors that are dissolved in a compatible solvent. Possible compatible solvents include, but are not limited to, ionic liquids, hydrocarbons (aliphatic, olefins, and aromatic), amines, esters, glymes, crown ethers, ethers and polyethers. In some cases it may be possible to dissolve one or more compatible solid precursors in one or more compatible liquid precursors. It will be apparent to one skilled in the art that by controlling the relative concentration levels of the various precursors within a gas pulse, it is possible to deposit mixed high-k films with desired stoichiometries.

Embodiments of the inventions may utilize a wide variety of metal precursors for depositing high-k films (e.g., HfO₂, HfON, ZrO₂, ZrON, TiO₂, TiON, Al₂O₃, La₂O₃, W₂O₃, CeO₂, Y₂O₃, or Ta₂O₅). For example, representative examples of Group IVB precursors include: Hf(O^{t}Bu)₄ (hafnium tert-butoxide, HTB), Hf(NEt₂)₄ (tetrakis(diethylamido)hafnium, TDEAH), Hf(NEtMe)₄ (tetrakis(ethylmethylamido)hafnium, TEMAH), Hf(NMe₂)₄ (tetrakis(dimethylamido)hafnium, TDMAH), Zr(O^{t}Bu)₄ (zirconium tert-butoxide, ZTB), Zr(NEt₂)₄ (tetrakis(diethylamido)zirconium, TDEAZ), Zr(NMeEt)₄ (tetrakis(ethylmethylamido)zirconium, TEMAZ), Zr(NMe₂)₄ (tetrakis(dimethylamido)zirconium, TDMAZ), Hf(mmp)₄, Zr(mmp)₄, Ti(mmp)₄, HfCl₄, ZrCl₄, TiCl₄, Ti(NⁱPr₂)₄, Ti(N¹Pr₂)₃, tris(N,N′-dimethylacetamidinato)titanium, ZrCp₂Me₂, Zr(^{t}BuCp)₂Me₂, Zr(NⁱPr₂)₄, Ti(OⁱPr)₄, Ti(O^{t}Bu)₄ (titanium tert-butoxide, TTB), Ti(NEt₂)₄ (tetrakis(diethylamido)titanium, TDEAT), Ti(NMeEt)₄ (tetrakis(ethylmethylamido)titanium, TEMAT), Ti(NMe₂)₄ (tetrakis(dimethylamido)titanium, TDMAT), and Ti(THD)₃ (tris(2,2,6,6-tetramethyl-3,5-heptanedionato)titanium).

A plurality of embodiments for forming gate spacers for semiconductor devices has been described. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. For example, the term “on” as used herein (including in the claims) does not require that a film “on” a substrate is directly on and in immediate contact with the substrate; there may be a second film or other structure between the film and the substrate.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method for forming a semiconductor device, the method comprising:
forming a patterned gate structure on a substrate, the patterned gate structure comprising an interface layer on the substrate, a high-k film on the interface layer, and a gate electrode on the high-k film;
depositing a nitride barrier layer on the patterned gate structure in a process chamber, the depositing comprising:
exposing the patterned gate structure to a process gas containing a nitride precursor at a substrate temperature below 400° C., and
maintaining a partial pressure of oxygen-containing gases below 1×10⁻⁴ Torr in the process chamber during the exposing;
depositing a spacer material on the nitride barrier layer; and
anisotropically etching the spacer material to form a gate spacer on the patterned gate structure.

2. The method of claim 1, wherein the gate electrode comprises poly Si.

3. The method of claim 1, wherein the gate electrode comprises a metal-containing layer.

4. The method of claim 3, wherein the metal-containing layer directly contacts the high-k film.

5. The method of claim 3, wherein the gate electrode comprises W, WN, WSi, Al, Mo, Ta, TaN, TaSiN, TaAlN, HfN, HfSiN, Ti, TiN, TiSiN, Mo, MoN, Re, Pt, or Ru, or a combination of two or more thereof.

6. The method of claim 1, wherein the high-k film comprises a metal oxide or a metal oxynitride.

7. The method of claim 6, wherein the high-k film comprises HfO₂, HfON, ZrO₂, ZrON, TiO₂, TiON, Al₂O₃, La₂O₃, W₂O₃, CeO₂, Y₂O₃, or Ta₂ O₅, or a combination of two or more thereof.

8. The method of claim 1, wherein the nitride barrier layer comprises SiN, SiCN, or a combination thereof.

9. The method of claim 1, wherein the spacer material comprises SiN, SiCN, or SiO₂, or a combination thereof.

10. The method of claim 1, wherein a thickness of the nitride barrier layer on sidewalls of the gate electrode is between about 10 angstrom and about 50 angstrom.

11. The method of claim 1, wherein, on sidewalls of the gate electrode, a thickness of the spacer material is greater than a thickness of the nitride barrier layer.

12. The method of claim 1, wherein the nitride barrier layer and the spacer material are selected from SiN and SiCN.

13. The method of claim 1, wherein the nitride barrier layer comprises SiN or SiCN and the spacer material comprises SiO₂.

14. The method of claim 1, wherein the nitride barrier layer is deposited by ALD or PEALD and the spacer material is deposited by CVD or PECVD.

15. A method for forming a semiconductor device, the method comprising:
forming a patterned gate structure on a substrate, the patterned gate structure comprising an interface layer on the substrate, a high-k film on the interface layer, a metal-containing gate electrode directly contacting the high-k film;
depositing a nitride barrier layer containing SiN or SiCN on the patterned gate structure in a process chamber, the depositing comprising:
exposing the patterned gate structure to a process gas containing a SiN or SiCN precursor at a substrate temperature below 400° C., and
maintaining a partial pressure of oxygen-containing gases below 1×10⁻⁴ Torr in the process chamber during the exposing;
depositing a SiO₂ spacer material on the nitride barrier layer; and
anisotropically etching the SiO₂ spacer material to form a gate spacer on the patterned gate structure.

16. The method of claim 15, wherein a thickness of the nitride barrier layer on sidewalls of the metal-containing gate electrode is between about 10 angstrom and about 50 angstrom.

17. The method of claim 15, wherein the nitride barrier material is deposited by ALD or PEALD and the SiO₂ spacer material is deposited by CVD or PECVD.

18. A method for forming a semiconductor device, the method comprising:
forming a patterned gate structure on a substrate, the patterned gate structure comprising an interface layer on the substrate, a high-k film on the interface layer, and a metal-containing gate electrode directly contacting the high-k film;
depositing a nitride barrier layer containing SiN or SiCN by ALD or PEALD on the patterned gate structure in a process chamber, wherein a thickness of the nitride barrier layer on sidewalls of the patterned gate structure is between about 10 angstrom and about 50 angstrom, the depositing comprising:
exposing the patterned gate structure to a process gas containing a SiN or SiCN precursor at a substrate temperature below 400° C., and
maintaining a partial pressure of oxygen-containing gases below 1×10⁻⁴ Torr in the process chamber during the exposing;
depositing a SiN or SiCN spacer material on the nitride barrier layer; and
anisotropically etching the spacer material to form a gate spacer on the patterned gate structure.

19. The method of claim 18, wherein the spacer material is deposited by CVD or PECVD.

20. The method of claim 18, wherein, on the sidewalls of the metal-containing gate electrode, a thickness of the spacer material is greater than a thickness of the nitride barrier layer.
